(19) United States
(12) Patent Application Publication
(10) Pub. No.: US 2016/0266058 A1
(43) Pub. Date: Sep. 15, 2016

(54) Reflective Photomask, Method for Inspecting Same and Mask Blank

(71) Applicant: Kabushiki Kaisha Toshiba, Tokyo (JP)

(72) Inventors: Masato NAKA, Yokohama (JP); Kosuke TAKAI, Yokohama (JP)

(73) Assignee: Kabushiki Kaisha Toshiba

(21) Appl. No.: 14/842,318

(22) Filed: Sep. 1, 2015

(30) Foreign Application Priority Data
Mar. 13, 2015 (JP) 2015-050963

(51) Int. Cl. G01N 23/227; G03F 1/50; G03F 1/52

(52) U.S. Cl. CPC G01N 23/227; G03F 1/52; G03F 1/50

(57) ABSTRACT

According to an embodiment, a reflective photomask includes a substrate, a first layer on the substrate and a second layer on the first layer. The first layer is capable of receiving a first light, and emitting electrons. The second layer has an opening of a predetermined pattern, and is capable of reflecting a second light.

### CROSS-REFERENCE TO RELATED APPLICATIONS

This application is based upon and claims the benefit of priority from Japanese Patent Application No. 2015-050963, filed on Mar. 13, 2015; the entire contents of which are incorporated herein by reference.

### FIELD

Embodiments are generally related to a reflective photomask, a method for inspecting the same, and a mask blank.

### BACKGROUND

Developing a lithography technology using Extreme Ultra Violet (EUV) light with a wavelength around 13.5 nm is under way for achieving a highly integrated semiconductor device. In such a short wavelength region, a reflective-type photomask is used for transferring the mask pattern onto a photoresist. The reflective photomask comprises a reflective layer having a multilayer structure of a molybdenum (Mo) film and silicon (Si) film, for example, which are alternately stacked, and the reflective layer may have a larger aspect ratio as the mask pattern becomes finer. Thus, a defect inspection of the mask pattern using an electron microscope or the like may become more difficult especially on a bottom of an opening in the reflective layer, where the pattern defects due to etching residue or half-etching are sometime found. As a result, the production yield of the semiconductor device may become lower.

### BRIEF DESCRIPTION OF THE DRAWINGS

FIG. 1 is a schematic cross-sectional view showing a reflective photomask according to an embodiment;

FIGS. 2A to 2C are schematic cross-sectional views showing a manufacturing process of the reflective photomask according to the embodiment;

FIGS. 3A and 3B are schematic cross-sectional views showing an inspection method of the reflective photomask according to the embodiment;

FIG. 4 is a schematic view showing an inspection apparatus of the reflective photomask according to the embodiment;

FIG. 5 is a flowchart showing the inspection method of the reflective photomask according to the embodiment;

FIGS. 6A to 6C are schematic views each showing an action of the inspection apparatus according to the embodiment; and

FIG. 7 is a schematic view showing another action of the inspection apparatus according to an embodiment.

### DETAILED DESCRIPTION

According to an embodiment, a reflective photomask includes a substrate, a first layer on the substrate and a second layer on the first layer. The first layer is capable of receiving a first light and emitting an electron. The second layer has an opening of a predetermined pattern, and is capable of reflecting a second light.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

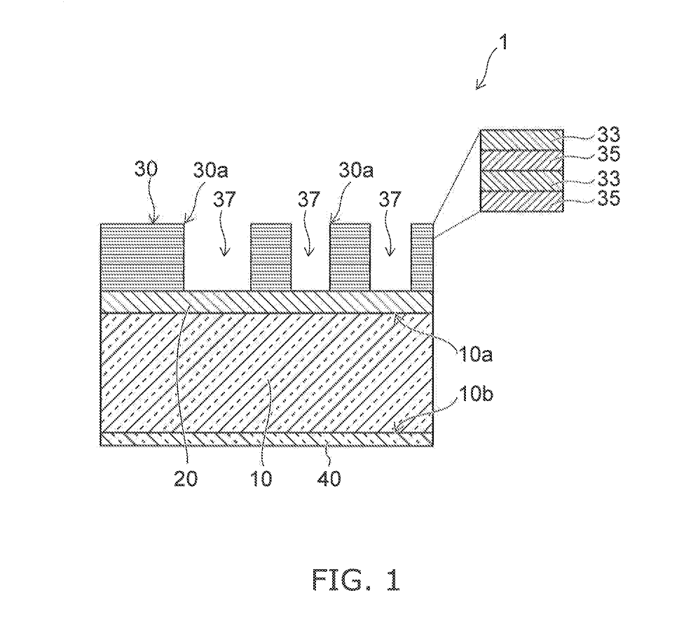

FIG. 1 is a schematic cross-sectional view showing a reflective photomask 1 according to an embodiment. The reflective photomask 1 includes, for example, a substrate 10, a first layer (hereinafter, a photoelectric layer 20), and a second layer (hereinafter, a reflective layer 30).

A glass substrate, for example, is used as the substrate 10. Preferably, the substrate 10 is a low thermal expansion glass (LTEM) doped with titanium (Ti) or the like. Accordingly, thermal expansion may be suppressed under irradiation of EUV light, Here, the EUV light is ultraviolet light, for example.

As shown in FIG. 1, the photoelectric layer 20 covers an upper face 10a of the substrate 10. There is used, as the photoelectric layer 20, a material including at least one element selected from the group including, for example, tantalum (Ta), ruthenium (Ru), gold (Au), molybdenum (Mo), silicon (Si), chrome (Cr), platinum (Pt), rhodium (Pd), lithium (Li), sodium (Na), potassium (K), rubidium (Rb), cesium (Cs), francium (Fr), and zirconium (Zr). It is preferred to use a material having a small work function such as alkali metal, for example, as the photoelectric layer 20.

The reflective layer 30, including a first film 33 and a second film 35 alternately stacked on the photoelectric layer 20, reflects EUV light. The second film 35 has a refractive index different from that of the first film with respect to EUV light. For example, the first film 33 is a molybdenum film and the second film 35 is a silicon film. There may be used, as the reflective layer 30, a multilayer film having approximately 40 pairs of a molybdenum film and a silicon film stacked thereon, for example. In addition, there may be other layers intervening between the reflective layer 30 and the photoelectric layer 20.

As shown in FIG. 1, the reflective layer 30 has an opening 37, In addition, the reflective layer 30 has a predetermined mask pattern 30a when seen from above.

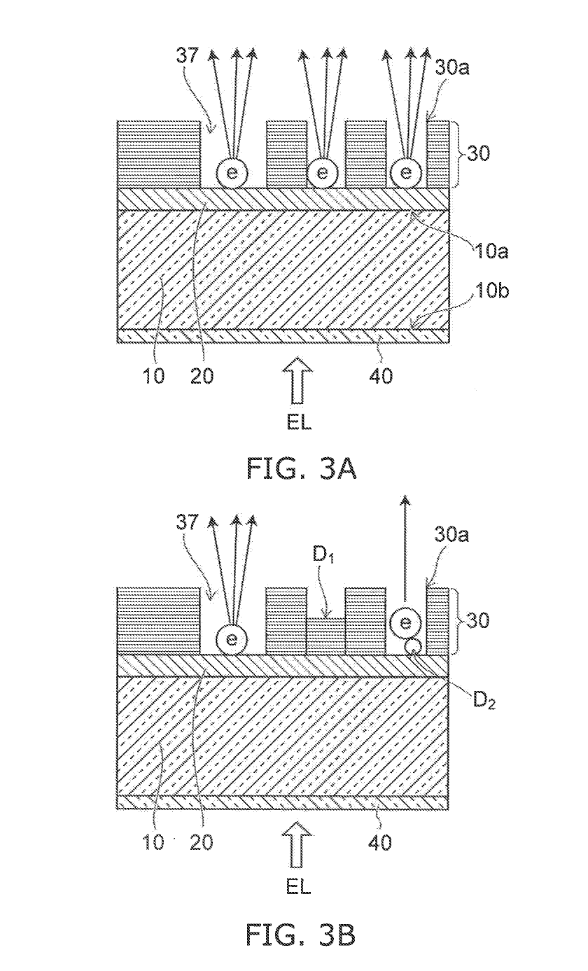

The reflective photomask 1 further includes a conductive film 40 covering a lower face 10b of the substrate 10. Provision of the conductive film 40 makes it possible to fix the reflective photomask 1 to a mask stage of an exposure apparatus using an electrostatic chuck. It is preferred to use, as the conductive film 40, a transparent conductive film such as ITO (Indium Tin Oxide), for example. In addition, a conductive film such as chromium nitride (CrN), for example, may be used as the conductive film 40, When the conductive film 40 does not transmit inspection light EL (see FIG. 3) described below, the conductive film 40 is formed after carrying out the defect inspection over the mask pattern.

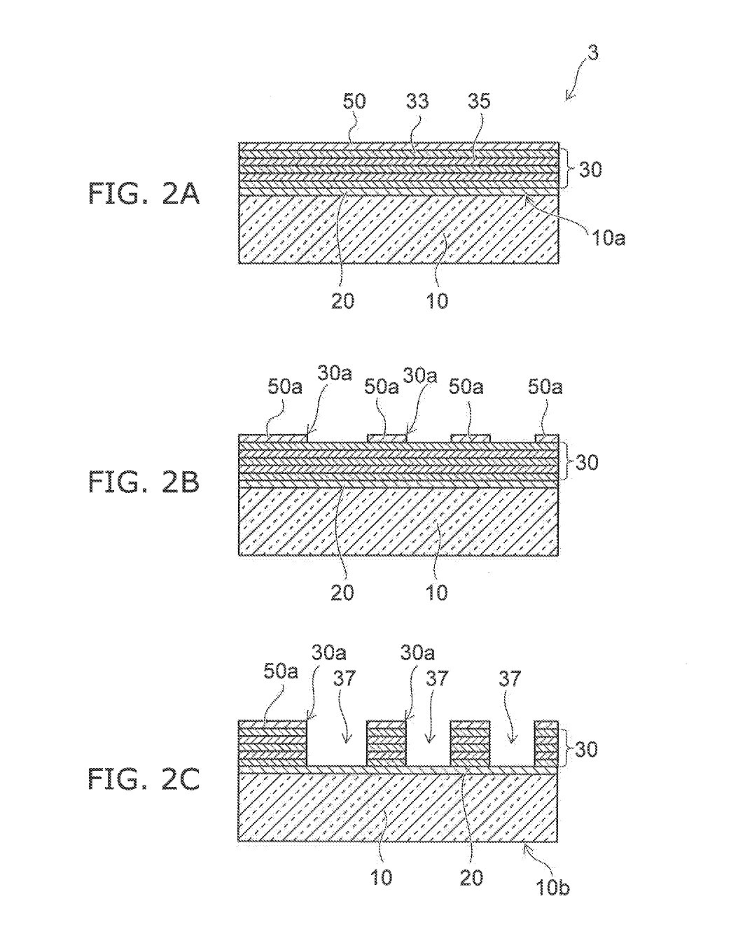

Referring to FIGS. 2A to 2C, a manufacturing method of the reflective photomask 1 according to an embodiment will be described. FIGS. 2A to 2C are schematic cross-sectional views showing a manufacturing process of the reflective photomask 1 in order.

The reflective photomask 1 is manufactured using a mask blank 3 shown in FIG. 2A, The mask blank 3 comprises the substrate 10, the photoelectric layer 20 covering an upper face 10a of the substrate 10, and the reflective layer 30 covering the photoelectric layer 20. The reflective layer 30 has a multilayer structure in which the first film 33 and the second film 35 are alternately stacked.

The mask blank 3 further includes a cap layer 50 provided on the reflective layer 30. The cap layer 50 may have a multilayer structure including, for example, a ruthenium (Ru) film, a tantalum nitride (TaN) film, and a tantalum oxide (TaO) film stacked in order. The top layer of the reflective layer 30 is a silicon layer, for example, and the ruthenium layer is formed directly on the silicon layer.

Next, as shown in FIG. 26 for example, the cap layer 50 is selectively removed using a resist mask formed by electron beam exposure, whereby forming an etching mask 50a, The etching mask 50a has a shape of the mask pattern 30a when seen from above.

As shown in FIG. 2C, the reflective layer 30 is selectively removed using the etching mask 50a, whereby forming an opening 37. Thus, the reflective layer 30 is formed into a shape of the mask pattern 30a when seen from above. In addition, the photoelectric layer 20 is exposed at the bottom surface of the opening 37. The photoelectric layer 20 is capable of emitting photoelectrons excited by the light transmitted through the substrate 10, when being not covered by the reflective layer 30.

Subsequently, forming the reflective photomask 1 is completed after removing the etching mask 50a and further forming the conductive film 40 on the lower face 10b of the substrate 10. The etching mask 50a may be left on the reflective layer 30.

FIGS. 3A and 3B are schematic sectional views showing an inspection method of the reflective photomask 1 according to an embodiment, FIG. 3A shows a case where the reflective layer 30 has no defect, and FIG. 3B shows a case where the reflective layer 30 includes defects D₁ and D₂.

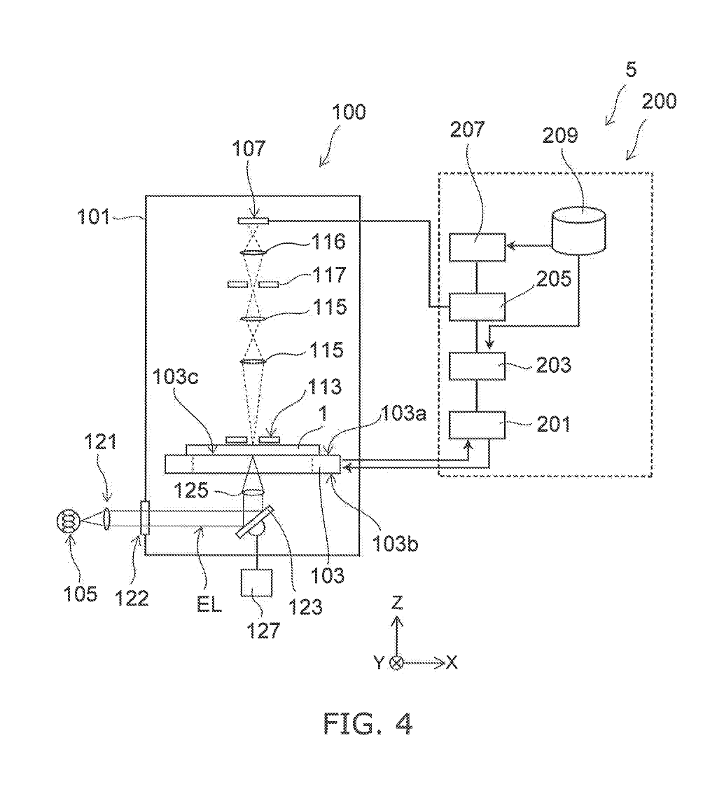

As shown in FIG. 3A, the lower face 10b of the substrate 10 is irradiated with inspection light EL. The inspection light EL is, for example, DUV (Deep Ultra Violet) light having a wavelength of 257 nanometers (nm). The inspection light EL propagates through the conductive film 40 and the substrate 10, and reaches the photoelectric layer 20. The inspection light EL excites electrons in the photoelectric layer 20. The electrons excited by the inspection light EL are emitted as photoelectrons from the photoelectric layer 20 to the opening 37, and detected by an electron detection part 107 (see FIG. 4).

When there exists a defect D₁ or D₂ in the opening 37 as shown in FIG. 3B, emission of photoelectrons is blocked, whereby, for example, decreasing brightness of a photoelectron image that is generated in the electron detection part 107. Thus, defects of the reflective layer 30 may be detected as low brightness part.

The defect D₁ is a half-etching defect, i.e. a part of the reflective layer 30 remaining on the bottom of the opening 37 for example, and decreases the amount of photoelectrons emitted from the photoelectric layer 20 to a surface level of the reflective layer 30. Thus, the brightness of the photoelectron image decreases in a part corresponding to the defect D₁. In addition, the defect D₂, which is foreign matter existing on the bottom of the opening 37, also decreases an emitted amount of photoelectrons. Then, the brightness decreases in a part of the photoelectron image corresponding to the defect D₂.

As a shape of the reflective layer 30 becomes finer, the aspect ratio thereof becomes larger, and the opening 37 becomes deeper, thus, making the detection of the defects D₁ and D₂ more difficult. For example, the defect inspection using a method in which the upper surface of the reflective layer 30 is irradiated with inspection light becomes undetectable; because the inspection light may not reach the bottom of the opening 3L Here, the “aspect ratio” refers to a height to width ratio of the reflective layer 30, and the aspect ratio becomes larger as the height of the reflective layer 30 becomes larger.

In addition, it also becomes difficult in the optical defect inspection method to resolve the pattern size exposed with the EUV light. Furthermore, it also becomes difficult in a defect inspection method using electron beams such as an electron microscope to irradiate the bottom of the opening 37 with electron beams.

In contrast, the photoelectric layer 20 is irradiated with the inspection light EL from the lower face 10b side of the substrate 10 in the defect inspection method according to the embodiment. Thus, the reflective layer 30 never blocks the inspection light, and the defects D₁ and D₂ existing on the bottom of the opening 37 may be certainly detected with an easier way.

The inspection light EL is not limited to DUV light having a wavelength of 257 nm, and there may be used light in a wavelength range of not less than 193 nm and not more than 1064 nm, for example. In addition, when less transparent material is used for the conductive film 40, the defect inspection may be performed before forming the conductive film 40 on the lower face 10b of the substrate 10.

FIG. 4 is a schematic view showing an inspection device 5 of the reflective photomask 1 according to an embodiment. The inspection device 5 includes, for example, an inspection unit 100 and a control unit 200.

The inspection unit 100 has, for example, a chamber 101, an inspection stage 103, a light irradiation part 105, and the electron detection part 107. The inside of the chamber 101 is decompressed using, for example, a vacuum pump or the like, and kept to a pressure lower than the exterior thereof. The inspection stage 103 and the electron detection part 107 are disposed inside the chamber 101.

A mask holding part for example, includes a driving part (not shown) in the inspection stage 103, Thus, the inspection stage 103 is movable in the X-direction, the Y-direction and the rotational direction about the Z-axis. The reflective photomask 1 is placed on the upper face 103a of the inspection stage 103. In addition, the inspection stage 103 has a light transmission part 103c for transmitting light that is emitted from the light irradiation part 105. The light transmission part 103c is made of, for example, a glass transmitting the inspection light EL. The light transmission part 103c may be a through-hole provided in the inspection stage 103.

The light irradiation part 105 is, for example, a UV laser that emits the DUV light having a wavelength of 257 nm. As shown in FIG. 4, the DUV light emitted from the light irradiation part 105 is collimated by a lens 121 to be parallel light. The light is then introduced from an optical window 122 provided in the chamber 101 into interior thereof.

Inside the chamber 101, the DUV light is reflected by a JO mirror 123, and is focused by a lens 125 on the lower face 103b of the inspection stage 103, for example. Further, the DUV light propagates through the light transmission part 103c and, the lower surface of the reflective photomask 1 is irradiated with the DUV light. Then, photoelectrons are emitted from the photoelectric layer 20 of the reflective photomask 1.

The electron detection part 107 is disposed above the inspection stage 103. The electron detection part 107 may be a TDI (Time Delay Integration) sensor, for example. The electron detection part 107 detects photoelectrons emitted from the reflective photomask 1. For example, the sensitivity of electron detection is improved by moving the inspection stage 103 in synchronization with the TDI sensor.

An electrostatic lens 115 and an aperture 117, for example, are disposed between the inspection stage 103 and the electron detection part 107. The electrostatic lens 115 and the aperture 117 collect electrons in the electron detection part 107. The electrostatic lens 115 and the aperture 117 adjust the focus or magnification to allow the photoelectrons emitted from the reflective photomask 1 to enter the electron detection part 107 efficiently.

Furthermore, an electrode 113 is disposed between the electrostatic lens 115 and the reflective photomask 1. For example, photoelectrons may be extracted from the reflective photomask 1 and directed to the electron detection part 107 by applying a positive electric potential to the electrode 113 at.

The control unit 200 includes, for example, a stage control part 201, a controller 203, an image-comparing part 205, a reference image generation part 207, and a database 209. The control unit 200 evaluates defects of the mask pattern, such as determining the presence or absence of the defects, based on an inspection image of the electron detection part 107, and outputs the result as defect information. The controller 203 is a CPU or a microprocessor, for example.

For example, the database 209 holds information such as design data of mask patterns, alignment information, calibration information, examination region, inspection mode, and the like. The reference image generation part 207 then generates a reference image based on the design data held in the database 209 and outputs the generated image to the image-comparing part 205. For example, the image-comparing part 205 obtains a photoelectron image from the electron detection part 107 and compares it with the reference image. Thus, presence or absence of defects of the mask pattern is determined based on the photoelectron image.

The embodiment is not limited to the example described above, and presence or absence of defects may be determined by, for example, comparing the photoelectron image at an inspection position obtained by the electron detection part 107 with a surrounding pattern or a photoelectron image of an adjacent mask pattern.

The controller 203 appropriately drives the inspection stage 103 via the stage control part 201, based on information such as inspection position, inspection condition, examination region, inspection mode and the like stored in the database 209. The information need not always be stored in the database 209, but may be input from outside.

The image-comparing part 205 outputs the presence or absence of defects to the controller 203. The controller 203 then evaluates the defect position based on defect information provided by the image-comparing part 205 and the position information provided by the stage control part 201. In addition, the controller 203 records the image obtained from the image-comparing part 205 and the position information of the defect in the database 209.

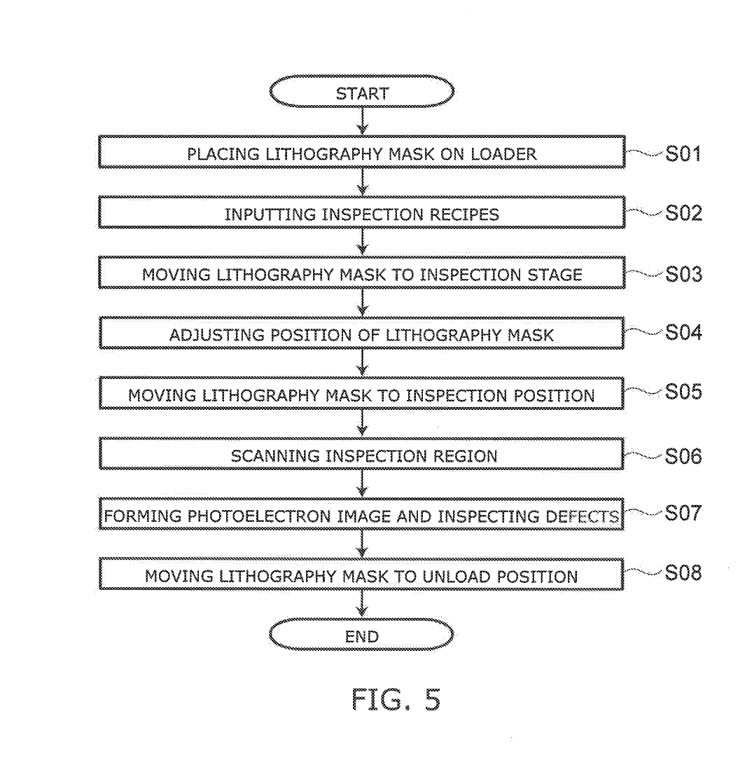

Next, an inspection method of the reflective photomask 1 according to an embodiment will be described, referring to FIGS. 4 and 5. FIG. 5 is a flowchart showing the inspection method of the reflective photomask 1 according to the embodiment.

Step S01: The reflective photomask 1 is placed on a mask loader (not shown).

Step S02: Inspection recipes such as alignment position (coordinates), an inspection region, an inspection mode, and the like, are input to the controller 203. Here, the “inspection mode” refers to a method of comparing the photoelectron image with the reference image, which is performed in the image-comparing part 205.

There are, for example, some modes such as Cell-to-Cell, Die-to-Die, Die-to-database, and the like, as the inspection modes. In the Cell-to-Cell mode, presence or absence of defects is determined by comparing the photoelectron image of the inspection position obtained by the electron detection part 107 with the photoelectron image of the pattern in the surroundings. In the Die-to-Die mode, the presence or absence of defects is determined by comparing the photoelectron image of a chip pattern at the inspection position with the photoelectron image of the adjacent chip pattern. In the Die-to-Database mode, the presence or absence of defects is determined by comparing the photoelectron image with the reference image based on the design data stored in the database 209.

Step S03: The reflective photomask 1 is transferred to the inspection stage 103. The reflective photomask 1 is placed on the inspection stage 103 and temporarily fixed thereon.

Step S04: The controller 203 moves the inspection stage 103 to the alignment position via the stage control part 201, and adjusts a position of the reflective photomask 1. For example, the controller 203 aligns the position in the X-direction, the Y-direction and the rotational direction about the Z-axis, while monitoring the mask pattern using an optical microscope (not shown), In addition to the position alignment using an optical microscope, a more highly precise alignment may also be performed using a photoelectron image of the electron detection part 107, for example.

Step S05: The controller 203 moves the inspection stage 103 from the alignment position to the inspection position via the stage control part 201. Then, the controller 203 activates the light irradiation part 105 to irradiate the lower face of the reflective photomask 1 with inspection light. For example, an operator monitors a photoelectron image of the electron detection part 107, determines the inspection condition based on lightness contrast and a sensor gain, or the like, and inputs it to the controller 203.

Step S06: The controller 203 drives the driving part of the inspection stage 103 via the stage control part 201, based on the input information of the inspection region, and starts scanning the inspection region of the reflective photomask 1.

Step S07: The controller 203 controls the electron detection part 107 to obtain a photoelectron image. Furthermore, the controller 203 stores, in the database 209, the photoelectron image obtained via the image-comparing part 205 in association with the data of the position on the reflective photomask 1 obtained via the stage control part 201.

The image-comparing part 205 analyzes the photoelectron image obtained from the electron detection part 107, and determines the presence or absence of defects. For example, when the inspection mode is Cell-to-Cell, the image-comparing part 205 generates a lightness difference image between a photoelectron image at an inspection position and a photoelectron image in the surroundings thereof, and determines the presence or absence of defects based on a preliminarily threshold value of the lightness. In addition, it may be possible to set a plurality of threshold values to determine a type of defect. When the inspection mode is Die-to-Die, the image-comparing part 205 generates a lightness difference image for the same part in the adjacent chip pattern, and determines the presence or absence, or the type of defects. In addition, when the inspection mode is Die-to-Database, the reference image generation part 207 generates a reference image based on the design information of the mask pattern stored in the database 209, and the image-comparing part 205 generates a lightness difference image between the photoelectron image of the electron detection part 107 and the reference image, and determines the presence or absence, or the type of defects. The reference image is generated depending on the sensor size of the electron detection part 107.

Such a method for determining presence of a defect may be performed real-time, or may be performed after scanning the inspection region. In addition, the determination result may be stored in the database 209 via the controller 203.

Step S08: when completing the scanning of the inspection region, the controller 203 causes the light irradiation part 105 to stop irradiation of the inspection light, and moves the inspection stage 103 to the mask unload position via the stage control part 201.

The aforementioned inspection flow is an example and thus the embodiments are not limited thereto. In addition, the controller 203 performs the aforementioned inspection flow by controlling the stage control part 201, the image-comparing part 205, the reference image generation part 207, and the database 209.

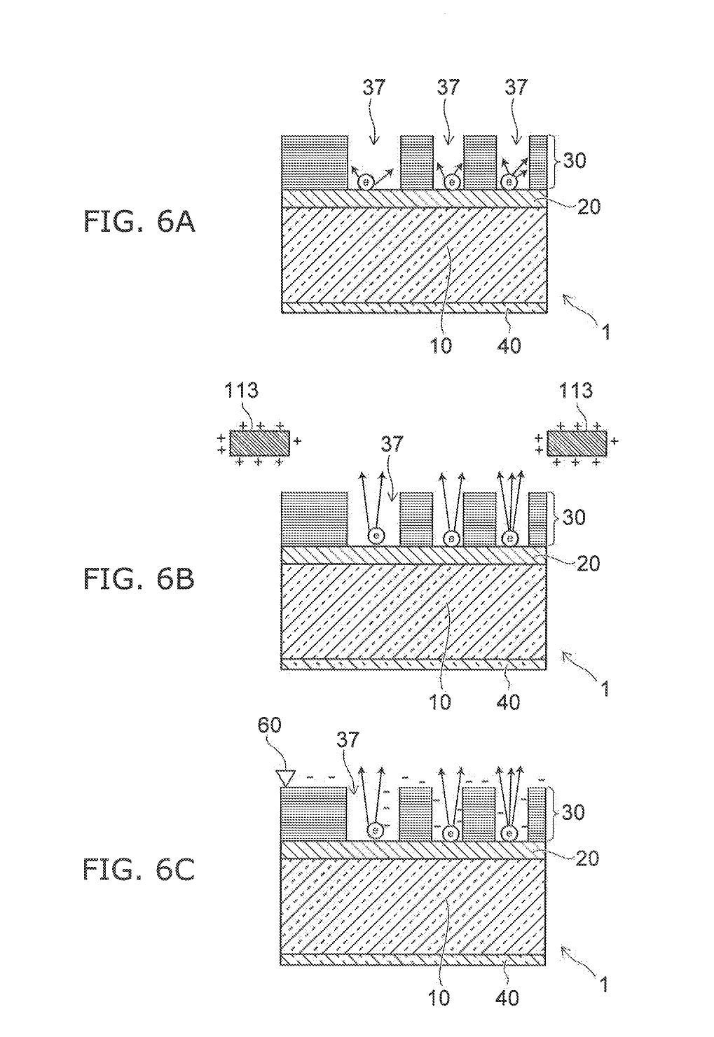

Referring to FIGS. 6A to 6C, the photoelectron extraction action of the inspection device 5 will be described. FIGS. 6A to 6C are schematic views each showing a cross section of the reflective photomask 1.

As shown in FIG. 6A, the direction in which photoelectrons are emitted from the photoelectric layer 20 is random. When the opening 37 is deep, photoelectrons loses energy by colliding with the side surface of the reflective layer 30. Thus, less number of photoelectrons is emitted out of the opening 37.

In the embodiment, as shown in FIG. 6B, the electrode 113 is disposed above the reflective photomask 1. The electrode 113 is then provided with a positive electric potential. Photoelectrons inside the opening 37 are extracted by the electric field generated by the electrode 113 and emitted out of the opening 37. Accordingly, the amount of the photoelectrons detected by the electron detection part 107 may be increased.

Further, it may be possible to apply a negative electric potential to the reflective layer 30 as shown in FIG. 6C. For example, at least one of the reflective layer 30 and the photoelectric layer 20 is electrically conductive. Thus, the reflective layer 30 and the photoelectric layer 20 are biased at a negative electric potential. The photoelectrons emitted from the photoelectric layer 20 are pushed by the electric field in the opening 37 and emitted outside. Thereby, the amount of photoelectrons detected by the electron detection part 107 may be increased by the negative electric potential at the reflective layer 30.

For example, an electrode terminal 60 contacting the reflective layer 30 of the reflective photomask 1 is provided on the inspection stage 103. Thus, it becomes possible to apply the negative electric potential to the reflective layer 30 and the photoelectric layer 20, The electrode 113 shown in FIG. 6B may be used at the same time with the electrode terminal 60 of the inspection stage 103.

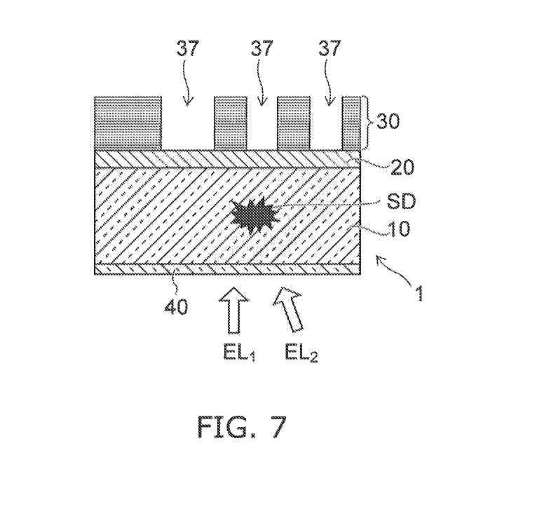

FIG. 7 is a schematic view showing another operation of the inspection device 5 according to an embodiment. FIG. 7 is a schematic view showing a cross section of the reflective photomask 1.

For example, the low thermal expansion glass (LTEM) used for the substrate 10 may include a defect SD, or the so-called stria, due to doping of impurities such as titanium. Accordingly, there is a concern that the inspection light EL is scattered, and the desired inspection position is not irradiated with the inspection light EL. Thus, it is preferable to irradiate the inspection position with the inspection light EL₁ and EL₂ by changing at least one of an incidence angle and an irradiating position in order to suppress the influence of the defect SD on the inspection.

For example, the inspection device 5 has, below the inspection stage 103, an irradiation adjusting mechanism 127 to change the reflection angle of mirror 123 and the position of the lens 125. Thus, it is possible to change an optical path of the inspection light EL by changing the incidence angle and the irradiation position with respect to the lower face 103b of the inspection stage 103.

For example, the electron detection part 107 integrates the amount of photoelectron detected within a predetermined time in order to form a photoelectron image. It is possible to reduce the influence of the defect SD in the substrate 10 by changing at least one of the incidence angle and the irradiation position of the inspection light EL during the predetermined time.

In the embodiment, the reflective photomask 1 includes the photoelectric layer 20 between the substrate 10 and the reflective layer 30. Thus, it becomes possible to perform defect inspection of a mask pattern by irradiating the lower face 10b of the substrate 10 with the inspection light EL. With the mask pattern inspection method according to the embodiment, it becomes possible to detect mask defects without being blocked by the reflective layer 30 having a large aspect ratio. Then, it becomes possible to increase the production yield of the reflective photomask and also the production yield of semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light reflective photomask comprising:
a substrate;
a first layer on the substrate and capable of receiving a first light and emitting electrons; and
a second layer on the first layer, the second layer having an opening of a predetermined pattern and being capable of reflecting a second light.

2. The light reflective photomask according to claim 1, wherein the first layer includes at least one element selected from the group of tantalum, ruthenium, gold, molybdenum, silicon, chrome, platinum, palladium, lithium, sodium, potassium, rubidium, zirconium, cesium, and francium.

3. The light reflective photomask according to claim 1, wherein the first layer is exposed at a bottom of the opening.

4. The light reflective photomask according to claim 1, wherein the second layer includes a first film and a second film, the second film being stacked alternately with the first film and having a refractive index different from the first film.

5. The light reflective photomask according to claim 1, wherein at least one of the first layer and the second layer is electrically conductive.

6. The light reflective photomask according to claim 1, wherein the substrate is a glass substrate.

7. The light reflective photomask according to claim 1, further comprising a transparent conductive film on the substrate, wherein the substrate is located between the first layer and the transparent conductive film.

8. The light reflective photomask according to claim 1, wherein the first light has a wavelength not less than 193 nanometers and not more than 1064 nanometers.

9. The light reflective photomask according to claim 1, wherein the second light is ultraviolet light.

10. A mask blank comprising:
a substrate;
a first layer on the substrate and capable of receiving a first light and emitting electrons; and
a second layer on the first layer, the second layer being capable of reflecting a second light.

11. A method for inspecting a photomask, the method comprising:
irradiating the photomask with the first light on a first side of the photomask; and
detecting photoelectrons emitted from the photomask on a second side opposite to the first side.

12. The method according to claim 11, wherein the photomask is irradiated with the first light changing at least one of an incident angle and an incident position at a surface of the photomask on the first side.

13. The method according to claim 11, further comprising:
forming a photoelectron image; and
evaluating a defect based on a lightness contrast of the photoelectron image.

14. The method according to claim 13, further comprising:
evaluating a type of the defect based on a brightness level of the photoelectron image.

15. The method according to claim 13, wherein
the evaluating a defect is performed by comparing the photoelectron image with a reference pattern.

16. The method according to claim 15, wherein
the reference pattern is one of a pattern adjacent to an inspection position, a chip pattern adjacent to the inspection position and a reference image based on design data of a mask pattern.

17. An apparatus of inspecting a photomask, the apparatus comprising:
a chamber;
a mask holding part provided in the chamber;
a light irradiation part irradiating the photomask with a first light from a first side of the mask holding part; and
a detection part detecting photoelectrons emitted from the photomask, the detection part being disposed on a second side of the mask holding part opposite to the first side.

18. The apparatus according to claim 17 further comprising a device for changing at least one of an incident angle and an incident position of the first light at a surface of the photomask on the first side.

19. The apparatus according to claim 17, further comprising:
a control part receiving an output of the detection part, wherein
the electron detection part outputs a photoelectron image; and
the control part evaluates a defect of the photomask based on the photoelectron image.

20. The apparatus according to claim 17, further comprising:
at least one of an electrode and an electrode terminal, the electrode being disposed between the electron detection part and the mask holding part and being capable of having higher potential than a potential of a mask holding part, and the electrode terminal being capable of contacting the photomask placed on the mask holding part.
